(19) United States
(12) Patent Application Publication
(10) Pub. No.: US 2022/0148888 A1
(43) Pub. Date: May 12, 2022

(54) SUBSTRATE PROCESSING METHOD, SEMICONDUCTOR PRODUCTION METHOD, AND SUBSTRATE PROCESSING APPARATUS

(71) Applicant: SCREEN Holdings Co., Ltd., Kyoto (JP)

(72) Inventors: Kenji KOBAYASHI, Kyoto-shi, Kyoto (JP); Masanobu SATO, Kyoto-shi, Kyoto (JP); Yuta NAKANO, Kyoto-shi, Kyoto (JP)

(21) Appl. No.: 17/440,212

(22) PCT Filed: Jan. 24, 2020
(86) PCT No.: PCT/JP2020/002540

§ 371 Date: Sep. 17, 2021

(30) Foreign Application Priority Data
Mar. 20, 2019 (JP) 2019-053333

(51) Int. Cl. H01L 21/67

(52) U.S. Cl. CPC H01L 21/6708; H01L 21/67115

(57) ABSTRACT

In a substrate processing method, a substrate with a pattern including a plurality of structures is processed. The substrate processing method includes a step of increasing hydrophilicity of respective surfaces of the structures, by executing predetermined processing on the structures with a non-liquid substance, from that before execution of the predetermined processing; and a step of supplying a processing liquid to the structures after the step of increasing hydrophilicity.

### TECHNICAL FIELD

The present invention relates to a substrate processing method, a semiconductor production method, and a substrate processing apparatus.

### BACKGROUND ART

The substrate processing apparatus disclosed in Patent Literature 1 executes processing for organic matter removal from a substrate. A plurality of microstructures are formed on the surface of the substrate. The microstructures are formed in a process before the substrate is carried into the substrate processing apparatus. For example, execution of etching processing through supply of a chemical solution to the substrate with a resist pattern formed thereon forms a plurality of microstructures on the surface of the substrate. Rinsing processing, water-repellent finishing processing, and drying processing are performed after the etching processing. The rinsing processing is processing to rinse away the chemical solution by supplying pure water to the substrate. The drying processing is processing to dry the substrate by rotating the substrate on a horizontal plane. During the drying processing, the microstructures may collapse due to the presence of the surface tension of the pure water.

The water-repellent finishing processing is executed before the drying processing in order to inhibit collapse of the microstructures. The water-repellent finishing processing is processing to form a water-repellent film (organic matter) on the surfaces of the microstructures by supplying a processing liquid containing a water repellent to the surface of the substrate. Through the water repellent finishing processing, the surface tension of the pure water acting on the microstructures can be reduced to inhibit collapse of the microstructures during the drying processing. However, the water-repellent film (organic matter) is unnecessary for a semiconductor product. As such, it is desired to remove the water-repellent film (organic matter) after the drying processing.

In view of the foregoing, the substrate processing apparatus executes processing to remove the water-repellent film (organic matter) by irradiating the substrate with ultraviolet rays. Specifically, the ultraviolet rays act on the water-repellent film (organic matter) present on the substrate to decompose and remove the water-repellent film (organic matter).

### CITATION LIST

### Patent Literature

[Patent Literature 1] Japanese Patent Application Laid-Open Publication No. 2018-166183

### SUMMARY OF INVENTION

### Technical Problem

However, the substrate processing apparatus disclosed in Patent Literature 1 only removes the organic matter by irradiating the substrate with ultraviolet rays after etching.

In other words, because the substrate is irradiated with the ultraviolet rays after etching, the effects of the ultraviolet rays do not affect etching. In yet other words, because the substrate is irradiated with the ultraviolet rays after processing with the processing liquid, the effects of the ultraviolet rays do not affect the processing with the processing liquid.

While at the same time, a pattern formed in a substrate is increasingly miniaturized in recent years. That is, each space between the microstructures on the surface of the substrate is increasingly reduced. As such, the surface tension (surface free energy) of the substrate may inhibit the processing liquid from infiltrating the space between the microstructures. As a result, there may remain a part of the substrate into which the processing liquid has sufficiently permeated and a part thereof into which the processing liquid has insufficiently permeated. This may cause uneven results in the processing of the microstructures with the processing liquid.

The present invention has been made in view of the foregoing and has its object of providing a substrate processing method, a semiconductor production method, and a substrate processing apparatus that can promote infiltration of a processing liquid into a space between structures on a substrate.

### Solution to Problem

According to an aspect of the present invention, a substrate with a pattern including a plurality of structures is processed according to a substrate processing method. The substrate processing method includes: increasing hydrophilicity of respective surfaces of the structures, by executing predetermined processing on the structures with a non-liquid substance, from that before execution of the predetermined processing; and supplying a processing liquid to the structures after the increasing hydrophilicity.

Preferably, the substrate processing method according to the present embodiment further includes supplying a removal liquid for removing oxide from the substrate to the structures before the increasing hydrophilicity.

In the substrate processing method according to the present invention, the predetermined processing is preferably processing to irradiate the structures with ultraviolet rays.

In the substrate processing method according to the present invention, the predetermined processing is preferably processing to irradiate the structures with plasma.

In the substrate processing method according to the present invention, the predetermined processing is preferably processing to supply oxygen or an allotrope of oxygen to the structures.

In the substrate processing method according to the present invention, the processing liquid preferably dissolves gas present in each space between adjacent structures of the structures.

Preferably, the substrate processing method according to the present invention further includes increasing hydrophobicity of the respective surfaces of the substrates, by supplying a hydrophobizing agent to the structures after the supplying a processing liquid, from that before supply of the hydrophobizing agent; and drying the substrate after the increasing hydrophobicity.

In the substrate processing method according to the present invention, each distance between adjacent structures of the structures preferably satisfies a prescribed condition. The prescribed condition is preferably that a same processing liquid as the processing liquid is unable to permeate into the each space between adjacent structures of the structures before the increasing hydrophilicity.

In the substrate processing method according to the present invention, the predetermined condition preferably includes a first condition and a second condition. Preferably, the first condition is that the same processing liquid as the processing liquid is unable to permeate into the each space between the adjacent structures through capillary action before the increasing hydrophilicity. Preferably, the second condition is that the processing liquid is enabled to permeate into the each space between the adjacent structures through the capillary action after the increasing hydrophilicity.

In the substrate processing method according to the present invention, in the increasing hydrophilicity, hydrophilicity of a surface of a recess of each of the structures is preferably increased from that before execution of the predetermined processing by executing the predetermined processing on the structures. The recess preferably recesses from a side wall surface of each of the structures in a direction intersecting a direction in which the structure extends.

According to another aspect of the present invention, in a semiconductor production method, a semiconductor is produced by processing a semiconductor substrate with a pattern including a plurality of structures, the semiconductor being the processed semiconductor substrate. The substrate processing method includes: increasing hydrophilicity of respective surfaces of the structures, by executing predetermined processing on the structures with a non-liquid substance, from that before execution of the predetermined processing; and supplying a processing liquid to the structures after the increasing hydrophilicity.

According to still another aspect of the present invention, a substrate processing apparatus processes a substrate with a pattern including a plurality of structures. The substrate processing apparatus includes a hydrophilizing section and a processing liquid supply section. The hydrophilizing section executes predetermined processing on the structures with a non-liquid substance to increase hydrophilicity of respective surfaces of the structures from that before execution of the predetermined processing. The processing liquid supply section supplies a processing liquid to the structures after time when the hydrophilicity of the respective surfaces of the structures is increased.

Preferably, the substrate processing apparatus according to the present invention further includes a removal liquid supply section. The removal liquid supply section preferably supplies a removal liquid to the structures before the hydrophilicity of the respective surfaces of the structures is increased, the removal liquid being for removing oxide from the substrate.

In the substrate processing apparatus according to the present invention, the predetermined processing is preferably processing to irradiate the structures with ultraviolet rays.

In the substrate processing method apparatus according to the present invention, the predetermined processing is preferably processing to irradiate the structures with plasma.

In the substrate processing apparatus according to the present invention, the predetermined processing is preferably processing to supply oxygen or an allotrope of oxygen to the structures.

In the substrate processing apparatus according to the present invention, the processing liquid preferably dissolves gas present in each space between adjacent structures of the structures.

Preferably, the substrate processing apparatus according to the present invention further includes a hydrophobizing section and a drying section. Preferably, the hydrophobizing section supplies a hydrophobizing agent to the structures after time when the processing liquid is supplied to the structures to increase hydrophobicity of the respective surfaces of the structures from that before supply of the hydrophobizing agent. Preferably, the drying section dries the substrate after time when the hydrophobicity of the respective surfaces of the structures is increased.

In the substrate processing apparatus according to the present invention, each distance between adjacent structures of the structures preferably satisfies a prescribed condition. The prescribed condition is preferably that a same processing liquid as the processing liquid is unable to permeate into each space between the adjacent structures before the hydrophilicity of the respective surfaces of the structures is increased.

In the substrate processing apparatus according to the present invention, the predetermined condition preferably includes a first condition and a second condition. The first condition is preferably that the same processing liquid as the processing liquid is unable to permeate into the space between the adjacent structures through capillary action before the hydrophilicity of the respective surfaces of the structures is increased. The second condition is preferably that the processing liquid is enabled to permeate into the space between the adjacent structures through capillary action after the hydrophilicity of the respective surfaces of the structures is increased.

In the substrate processing apparatus according to the present invention, it is preferable that the hydrophilizing section increases hydrophilicity of a surface of a recess of each of the structures from that before execution of the predetermined processing by executing the predetermined processing on the structures. The recess preferably recesses from a side wall surface of each of the structures in a direction intersecting a direction in which the structure extends.

### Advantageous Effects of Invention

According to the present invention, a substrate processing method, a semiconductor producing method, and a substrate processing apparatus can be provided that can promote infiltration of a processing liquid into a space between structures on a substrate.

### BRIEF DESCRIPTION OF DRAWINGS

FIG. 1 is a schematic plan view of a substrate processing apparatus according to a first embodiment of the present invention.

FIG. 2A is a schematic cross-sectional view of an example of a substrate in the first embodiment. FIG. 2B is a schematic cross-sectional view of another example of the substrate in the first embodiment.

FIG. 3 is a schematic cross-sectional view of a hydrophilizing apparatus in the first embodiment.

FIG. 4 is a schematic cross-sectional view of a processing apparatus in the first embodiment.

FIG. 5 is a graph representation showing the relationship between permeation time and of contact angle of a processing liquid in the first embodiment.

FIG. 6 is a flowchart depicting a substrate processing method according to the first embodiment.

FIG. 7 is a flowchart depicting Step S1 in FIG. 7.

FIG. 8 is a schematic plan view of a processing apparatus according to a variation of the first embodiment.

FIG. 9 is a schematic cross-sectional view of a processing apparatus according to a second embodiment of the present invention.

FIG. 10 is a schematic cross-sectional view of a hydrophilizing nozzle in the second embodiment.

FIG. 11 is a schematic cross-sectional view of a processing apparatus according to a third embodiment of the present invention.

FIG. 12 is a schematic cross-sectional view of a processing apparatus according to a fourth embodiment of the present invention.

FIG. 13 is a flowchart depicting a substrate processing method according to the fourth embodiment.

### DESCRIPTION OF EMBODIMENTS

Embodiments of the present invention will be described below with reference to the accompanying drawings. Note that elements that are the same or equivalent are indicated by the same reference signs in the drawings and description thereof is not repeated. In the embodiments of the present invention, an X axis, a Y axis, and a Z axis are perpendicular to one another. The X axis and the Y axis are parallel to a horizontal direction while the Z axis is parallel to a vertical direction. Note that shaded lines indicating cross section are omitted as appropriate for simplification of the drawings.

### First Embodiment

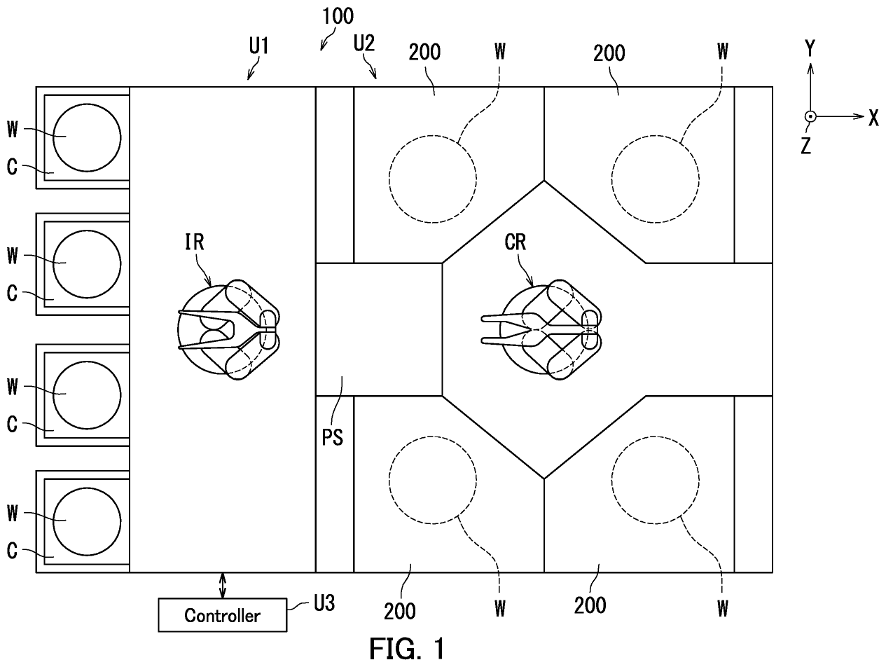

The following describes a substrate processing apparatus 100 according to a first embodiment of the present invention with reference to FIGS. 1 to 7. The substrate processing apparatus 100 processes a substrate W with a processing liquid. Hereinafter, the processing liquid is referred to as “processing liquid LQ”. Examples of the substrate W include a semiconductor wafer, a substrate for liquid crystal display device use, a substrate for plasma display use, a substrate for field emission display (FED) use, a substrate for optical disk use, a substrate for magnetic disk use, a substrate for optical magnetic disk use, a substrate for photomask use, a ceramic substrate, and a substrate for solar cell use. The substrate W is substantially disk shaped, for example. In the following description of the first embodiment, the substrate W is a semiconductor substrate.

First, the substrate processing apparatus 100 will be described with reference to FIG. 1. FIG. 1 is a schematic plan view of the substrate processing apparatus 100. As illustrated in FIG. 1, the substrate processing apparatus 100 includes an indexer unit U1, a processing unit U2, and a controller U3. The indexer unit U1 includes a plurality of substrate containers C and an indexer robot IR. The processing unit U2 includes a plurality of processing apparatuses 200, a transport robot CR, and a delivery section PS.

Each of the substrate containers C accommodates a plurality of substrates W in a stacked manner. The indexer robot IR takes an unprocessed substrate W out of any of the substrate containers C and delivers the taken substrate W to the delivery section PS. The substrate W taken out of the substrate container C is then placed on the delivery section PS. The transport robot CR receives the unprocessed substrate W from the delivery section PS and carries the received substrate W into any one of the processing apparatuses 200.

Then, the processing apparatus 200 processes the unprocessed substrate W. The processing apparatuses 200 each are of a single-wafer type in which unprocessed substrates W are processed on a wafer-by-wafer basis. The processing apparatuses 200 each process a substrate W with the processing liquid LQ.

After the processing by the processing apparatus 200, the transport robot CR takes the processed substrate W out of the processing apparatus 200 and delivers the substrate W to the delivery section PS. The substrate W processed by the processing apparatus 200 is then placed on the delivery section PS. The indexer robot IR receives the processed substrate W from the delivery section PS and accommodates the substrate W in any of the substrate containers C.

The controller U3 controls the indexer unit U1 and the processing unit U2. The controller U3 includes a computer. Specifically, the controller U3 includes a storage device and a processor such as a central processing unit (CPU). The storage device stores data and computer programs therein. The storage device includes a main storage device such as semiconductor memory and an auxiliary storage device such as either or both semiconductor memory and a hard disk drive. The storage device may include a removable medium. The processor of the controller U3 executes the computer programs stored in the storage device of the controller U3 to control the indexer unit U1 and the processing unit U2.

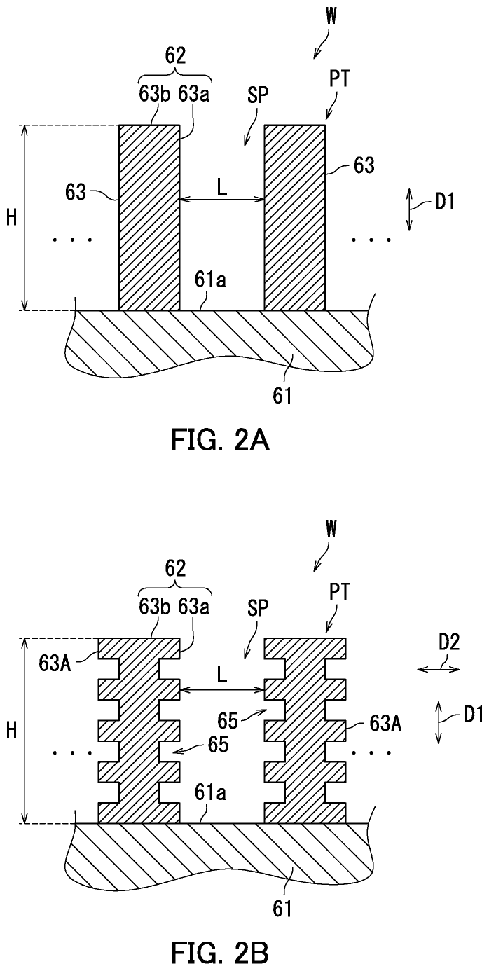

The substrate W will be described next with reference to FIGS. 2A and 2B. FIG. 2A is a schematic cross-sectional view of an example of the substrate W. In FIG. 2A, a part of the surface of the substrate W is illustrated in an enlarged scale. As illustrated in FIG. 2A, the substrate W includes a substrate body 61 and a pattern PT. The substrate body 61 is made of silicon. The pattern PT is a micropattern, for example. The pattern PT includes a plurality of structures 63. The structures 63 are microstructures, for example.

Each of the structures 63 extends in a first direction D1. The first direction D1 is a direction intersecting a surface 61a of the substrate body 61. In the first embodiment, the first direction D1 is a direction substantially perpendicular to the surface 61a of the substrate body 61. Surfaces 62 of the structures 63 each include a side wall surface 63a and a top wall surface 63b.

Each of the structures 63 is composed of a single layer or multiple layers. In a case in which each structure 63 is composed of a single layer, the structure 63 is an insulating layer, a semiconductor layer, or a conductive layer. In a case in which each structure 63 is composed of multiple layers, the structure 63 may include an insulating layer, a semiconductor layer, or a conductive layer, or may include at least two of the insulating layer, the semiconductor layer, and the conductive layer.

The insulating layer is a silicon oxide film or a silicon nitride film, for example. The semiconductor layer is a polysilicon film or an amorphous silicon film, for example. The conductive layer is a metal film, for example. The metal film is a film containing at least one of titanium, tungsten, copper, and aluminum, for example.

FIG. 2B is a schematic cross-sectional view of another example of the substrate W. In FIG. 2B, a part of the surface of the substrate W is illustrated in an enlarged scale. As illustrated in FIG. 2B, each of the structures 63 has at least one recess 65. In the example illustrated in FIG. 2B, each of the structures 63 has a plurality of recesses 65. Each of the recesses 65 recesses from the side wall surface 63a of the structure 63 in a direction intersecting a direction in which the structure 63 extends. In the first embodiment, the direction in which the structure 63 extends is substantially parallel to the first direction D1. Specifically, each of the recesses 65 recesses in a second direction D2. The second direction D2 is a direction along the surface 61a of the substrate body 61. Specifically, the second direction D2 is a direction intersecting the first direction D1. In the first embodiment, the second direction D2 is a direction substantially perpendicular to the first direction D1.

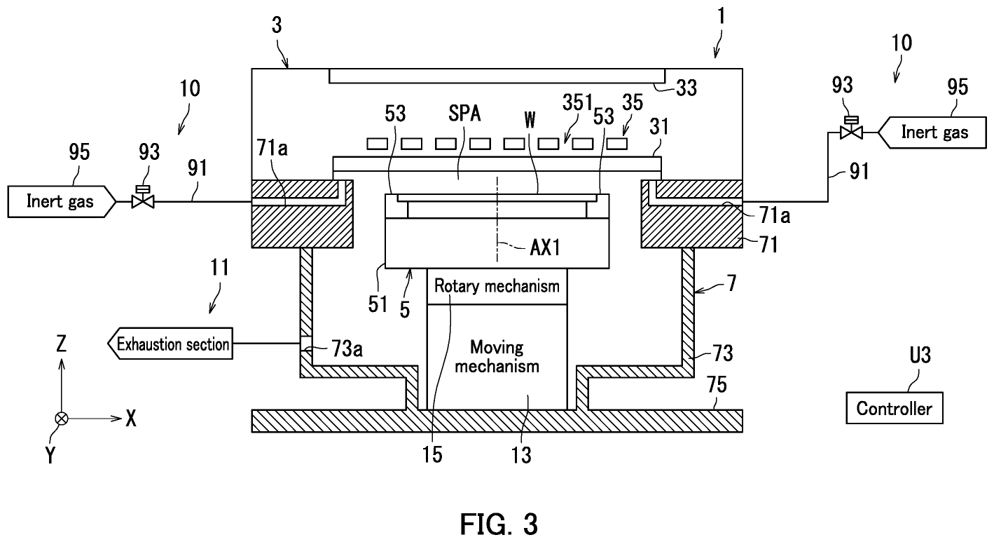

A hydrophilizing apparatus 1 included in the substrate processing apparatus 100 will be described next with reference to FIG. 3. FIG. 3 is a schematic cross-sectional view of the hydrophilizing apparatus 1. The hydrophilizing apparatus 1 corresponds to an example of a “hydrophilizing section”. The hydrophilizing apparatus 1 is installed in the delivery section PS illustrated in FIG. 1, for example. Note that the location where the hydrophilizing apparatus 1 is installed is not particularly limited. For example, the hydrophilizing apparatus 1 may be included in the substrate processing apparatus 100 in place of one of the processing apparatuses 200 illustrated in FIG. 1.

The hydrophilizing apparatus 1 executes predetermined processing with a non-liquid substance on the structures 63 of the substrate W to increase the hydrophilicity of the respective surfaces 62 of the structures 63 from that before execution of the predetermined processing. The hydrophilicity refers to the degree of ease with which a liquid adheres to the surface of a solid. The higher the hydrophilicity is, the easier it is for the liquid to adhere to the surface of the solid. That is, the higher the hydrophilicity is, the easier it is for the surface of the solid to get wet. The hydrophilicity can be represented by a contact angle CA. The contact angle CA is an angle, when a solid surface is in contact with a liquid and a gas, between the liquid surface and the solid surface at a boundary of the three phases in contact with one another. The narrower the contact angle CA is, the higher the hydrophilicity is. The narrower the contact angle CA is, the larger the surface tension of the solid is. The higher the hydrophilicity is, the larger the surface tension of the solid is. The “non-liquid substance” is electromagnetic waves or a material that is not a liquid. The “electromagnetic waves” is light, for example. The “material that is not a liquid” is plasma or gas, for example. In the present description, the term “predetermined processing” refers to “predetermined processing with the non-liquid substance”. The “predetermined processing with the non-liquid substance” refers to “processing using the non-liquid substance”.

In particular, in the first embodiment, the hydrophilizing apparatus 1 executes, before the processing liquid LQ is supplied to the substrate W, the predetermined processing on the structures 63 of the substrate W to increase the hydrophilicity of the respective surfaces 62 of the structures 63 from that before execution of the predetermined processing. Therefore, the surface tension of the surfaces 62 of the structures 63 can be increased from that before execution of the predetermined processing. As a result, infiltration of the processing liquid LQ into a space SP between the structures 63 of the substrate W can be promoted when processing the substrate W with the processing liquid LQ.

As a result of infiltration of the processing liquid LQ into the space SP between the structures 63 being promoted, the processing liquid LQ can quickly and substantially uniformly permeate into the space SP between the structures 63 throughout the entire substrate W. Therefore, unevenness in results of the processing of the structures 63 with the processing liquid LQ can be reduced from occurring. For example, in a case in which the processing liquid LQ is an etching solution, unevenness in results of etching of the structures 63 can be reduced from occurring. Furthermore, the processing liquid LQ is allowed to quickly permeate into the space SP between the structures 63, which can achieve effective processing of the structures 63 with the processing liquid LQ. For example, in a case in which the processing liquid LQ is an etching solution, the structures 63 can be effectively etched.

Note that it is only required that at least the side wall surface 63a of the surface 62 of each structure 63 as illustrated in FIG. 2A have hydrophilicity increased from that before execution of the predetermined processing. Furthermore, in the first embodiment, the substrate W is dried before execution of the predetermined processing, for example. The term “dry” refers to a state in which a liquid is removed from the substrate W.

As to the substrate W illustrated in FIG. 2B, the hydrophilizing apparatus 1 executes, before the processing liquid LQ is supplied to the substrate W, the predetermined processing on the structures 63 to increase the hydrophilicity of the side wall surface 63a and the top wall surface 63b of each of the structures 63 and the hydrophilicity of the surface of each recess 65 of the structures 63 from those before execution of the predetermined processing. Therefore, in processing the substrate W with the processing liquid LQ, infiltration of the processing liquid LQ can be promoted in the substrate W not only into the space SP between the structures 63 but also into each of the recesses 65. As a result, the processing liquid LQ is allowed to quickly permeate into the recesses 65, thereby achieving effective processing of the recesses 65 with the processing liquid LQ.

Note that the surfaces 62 of the structures 63 as illustrated in FIG. 2B each include the surfaces of the recesses 65. It is only required that the hydrophilicity of the side wall surface 63a and the hydrophilicity of the surfaces of the recesses 65 of the surface of each structure 63 be increased from those before execution of the predetermined processing.

In the following description, increasing the hydrophilicity of the respective surfaces 62 of the structures 63 from that before execution of the predetermined processing may be referred to as “hydrophilization”. Also, “permeation” refers to the processing liquid LQ reaching the surface 61a or the vicinity of the surface 61a of the substrate body 61 through infiltration into the space SP between the structures 63.

In particular, the predetermined processing is processing to irradiate the structures 63 of the substrate W with ultraviolet rays in the first embodiment. That is, the hydrophilizing apparatus 1 irradiates the structure 63 of the substrate W with the ultraviolet rays to increase the hydrophilicity of the respective surfaces 62 of the structures 63 from that before irradiation with the ultraviolet rays. The energy of the ultraviolet rays is greater than the energy of visible light, and effective hydrophilization of the surfaces 62 of the structures 63 can therefore be achieved.

Specifically, the hydrophilizing apparatus 1 includes an ultraviolet irradiating section 3, a substrate holding section 5, an accommodation section 7, a plurality of gas supply sections 10, an exhaustion section 11, a moving mechanism 13, and a rotary mechanism 15 as illustrated in FIG. 2.

The substrate holding section 5 holds the substrate W. Specifically, the substrate holding section 5 rotates the substrate W about a rotation axis AX1 of the substrate holding section 5 while horizontally holding the substrate W. The rotation axis AX1 is substantially parallel to the vertical direction and passes through the center of the substrate W. More specifically, the substrate holding section 5 includes a spin base 51 and a plurality of chuck members 53. The chuck members 53 are provided on the spin base 51 in a circumferential direction about the rotation axis AX1. The chuck members 53 hold the substrate W in a horizontal posture. The spin base 51 has a substantially disk-like shape or a substantially columnar shape and supports the chuck members 53 in a horizontal posture. When the spin base 51 is rotated about the rotation axis AX1, the substrate W held by the chuck members 53 rotates about the rotation axis AX1.

The moving mechanism 13 moves the substrate holding section 5 in the vertical direction. Specifically, the moving mechanism 13 reciprocates the substrate holding section 5 between a first point and a second point. The first point refers to a point where the substrate holding section 5 is close to the ultraviolet irradiating section 3. FIG. 2 illustrates the substrate holding section 5 positioned at the first point. The second point refers to a point where the substrate holding section 5 is far from the ultraviolet irradiating section 3. The first point is a point at which the substrate holding section 5 is positioned when processing using ultraviolet rays is executed on the substrate W. The second point is a point at which the substrate holding section 5 is positioned when the substrate W is delivered or received. The moving mechanism 13 includes a ball screw mechanism, for example.

The rotary mechanism 15 rotates the substrate holding section 5 about the rotation axis AX1. Accordingly, the substrate W held by the substrate holding section 5 rotates about the rotation axis AX1. The rotary mechanism 15 includes a motor, for example.

The ultraviolet irradiating section 3 and the substrate holding section 5 are arranged along the rotation axis AX1 and opposite to each other. The ultraviolet irradiating section 3 is opposite to the substrate W with a space SPA therebetween. The ultraviolet irradiating section 3 generates ultraviolet rays. The space SPA is a space between the ultraviolet irradiating section 3 and the substrate holding section 5. The ultraviolet irradiating section 3 irradiates the surfaces 62 of the structures 63 of the substrate W with the ultraviolet rays to increase the hydrophilicity of the respective surfaces 62 of the structures 63 from that before irradiation with the ultraviolet rays. Presumably, a reason for the increase in the hydrophilicity is that irradiation with the ultraviolet rays promote oxidation of the surfaces 62 of the structures 63.

In particular, the ultraviolet irradiating section 3 in the first embodiment irradiates the surfaces 62 of the structures 63 of the substrate W with the ultraviolet rays during rotation of the substrate W. Therefore, the surfaces 62 of the structures 63 of the substrate W can be irradiated more uniformly with the ultraviolet rays than in a case in which a stationary substrate W is irradiated with the ultraviolet rays. As a result, the hydrophilicity of the respective surfaces 62 of the structures 63 of the substrate W can be increased effectively from that before irradiation with the ultraviolet rays.

Specifically, the ultraviolet irradiating section 3 includes an electrode 33, an electrode 35, and a quartz glass plate 31. The electrode 33 has a substantially flat plate shape. The electrode 35 has a substantially flat plate shape. The electrode 35 has a plurality of openings 351. The openings 351 each extend through the electrode 35 in the vertical direction. The electrode 35 is opposite to the electrode 33 with a space therebetween. The electrode 35 is located on a side of the quartz glass plate 31 opposite to the electrode 33. The quartz glass plate 31 is located on a side of the substrate W opposite thereto. The quartz glass plate 31 transmits the ultraviolet rays and has heat resistance and corrosion resistance. The quartz glass plate 31 is an insulator.

A gas for electric discharge is present in the space between the electrode 33 and the electrode 35. A high-frequency high voltage is applied between the electrode 33 and the electrode 35. As a result, the gas for electric discharge is excited to enter an excimer state. The gas for electric discharge generates ultraviolet rays when returning to the ground state from the excimer state. The ultraviolet rays pass through the openings 351 of the electrode 35 and further pass through the quartz glass plate 31 to be radiated on the substrate W. Note that the hydrophilizing apparatus 1 includes a high-voltage source that applies the high-frequency high voltage between the electrode 33 and the electrode 35. No particular limitations are placed on the configuration and shape of the ultraviolet irradiating section 3 so long as the ultraviolet irradiating section 3 is capable of executing irradiation with ultraviolet rays.

The accommodation section 7 accommodates the substrate holding section 5, the moving mechanism 13, and the rotary mechanism 15. The ultraviolet irradiating section 3 blocks the upper opening of the accommodation section 7. As such, a combination of the ultraviolet irradiating section 3 and the accommodation section 7 functions as a chamber.

Specifically, the accommodation section 7 includes a cylindrical portion 71, a side wall portion 73, and a bottom portion 75. The lower part of the cylindrical portion 71 is connected to the upper part of the side wall portion 73. The lower part of the side wall portion 73 is connected to the bottom portion 75. The cylindrical portion 71 has a plurality of through holes 71a. Each of the through holes 71a extends through the cylindrical portion 71 and communicates with the space SPA. The side wall portion 73 has a through hole 73a. The through hole 73a extends through the side wall portion 73.

The gas supply sections 10 each supply an inert gas to the space SPA through a corresponding one of the through holes 71a. The inert gas is nitrogen or argon, for example. Specifically, each of the gas supply sections 10 includes a pipe 91, an on-off valve 93, and a gas container 95. The gas container 95 contains the inert gas that is to be supplied to the space SPA. The gas container 95 is connected to an end of the pipe 91. The on-off valve 93 is provided in the pipe 91 to switch between opening and closing of the pipe 91. The other end of the pipe 91 is connected to the through hole 91a. The exhaustion section 11 exhausts the gas inside the accommodation section 7 from the through hole 73a.

The controller U3 controls the hydrophilizing apparatus 1. Specifically, the processor of the controller U3 runs the computer programs stored in the storage device of the controller U3 to control the hydrophilizing apparatus 1.

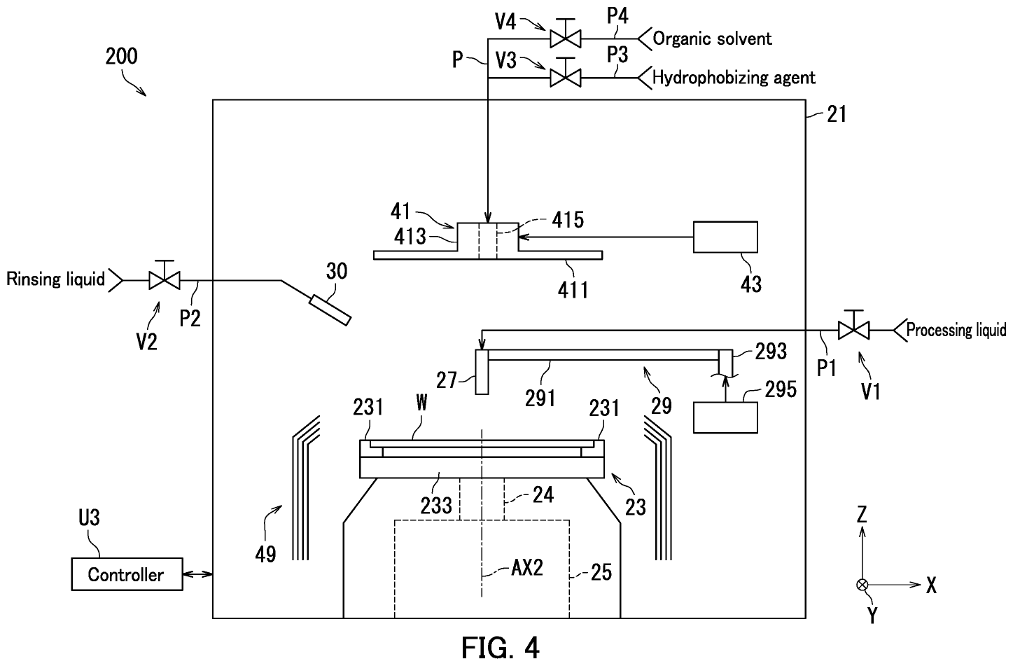

Next, the processing apparatuses 200 will be described with reference to FIG. 4. FIG. 4 is a schematic cross-sectional view of a processing apparatus 200. As illustrated in FIG. 4, the processing apparatus 200 processes the substrate W by supplying the processing liquid LQ to the substrate W while rotating the substrate W after the hydrophilicity of the respective surfaces 62 of the structures 63 of the substrate W is increased by the hydrophilizing apparatus 1. Specifically, the processing apparatuses 200 each include a chamber 21, a spin chuck 23, a spin shaft 24, a spin motor 25, a nozzle 27, a nozzle moving section 29, a nozzle 30, a plurality of guards 49, a valve V1, a valve V2, a pipe P1, and a pipe P2.

The chamber 21 is substantially box-shaped. The chamber 21 accommodates the substrate W, the spin chuck 23, the spin shaft 24, the spin motor 25, the nozzle 27, the nozzle moving section 29, the nozzle 30, a part of the pipe P1, and a part of the pipe P2.

The spin chuck 23 holds and rotates the substrate W. Specifically, the spin chuck 23 rotates the substrate W about a rotation axis AX2 of the spin chuck 23 while holding the substrate W horizontally in the chamber 21.

The spin chuck 23 includes a plurality of chuck members 231 and a spin base 233. The chuck members 231 are arranged on the spin base 233. The chuck members 231 hold the substrate W in a horizontal posture. The spin base 233 is substantially disk shaped and supports the chuck members 231 in a horizontal posture.

The spin shaft 24 is fixed to the spin base 233. The spin shaft 24 is also fixed to the drive shaft of the spin motor 25. The spin motor 25 rotates the spin shaft 24 to rotate the spin base 233 about the rotation axis AX2. Accordingly, the substrate W held by the chuck members 231 provided on the spin base 233 rotates about the rotation axis AX2.

The nozzle 27 supplies the processing liquid LQ to the structures 63 of the rotating substrate W after the hydrophilicity of the respective surfaces 62 of the structures 63 of the substrate W is increased by the hydrophilizing apparatus 1. Therefore, the processing liquid LQ is allowed to effectively permeate into the space SP between the structures 63 of the substrate W. This can achieve effective processing of the structures 63 with the processing liquid LQ. The nozzle 27 corresponds to an example of a “processing liquid supply section”.

In particular, the processing liquid LQ dissolves the gas present in the space SP between adjacent structures 63 of the structures 63 in the first embodiment. As a result, the processing liquid LQ is allowed to further quickly permeate into the space SP between the structures 63 of the substrate W.

The processing liquid LQ is a chemical solution (e.g., an etching solution), for example. Examples of the chemical solution include hydrofluoric acid (HF), fluorine nitric acid (mixed liquid of hydrofluoric acid and nitric acid (HNO₃), buffered hydrofluoric acid (BHF), ammonium fluoride, mixed liquid of hydrofluoric acid and ethylene glycol (HFEG), phosphoric acid (H₃PO₄), sulfuric acid, acetic acid, nitric acid, hydrochloric acid, dilute hydrofluoric acid (DHF), ammonia water, hydrogen peroxide solution, organic acids (e.g., citric acid and oxalic acid), organic alkalis (e.g., tetramethylammonium hydroxide (TMAH)), sulfuric acid-hydrogen peroxide mixture (SPM), ammonia hydrogen peroxide (SC1) solution, hydrochloric acid hydrogen peroxide (SC2) solution, a surfactant, and a corrosion inhibitor. Note that no particular limitations are placed on the type of the processing liquid LQ so long as the processing liquid LQ is capable of processing the substrate W.

The nozzle moving section 29 moves the nozzle 27 between a processing point and a retraction point. The processing point refers to a point located above the substrate W. The nozzle 27 at the processing point supplies the processing liquid LQ to the surfaces 62 of the structures 63 of the substrate W. The retraction point refers to a point outward of the substrate W in the radial direction of the substrate W.

Specifically, the nozzle moving section 29 includes an arm 291, a rotary shaft 293, and a nozzle moving mechanism 295. The arm 291 extends in the substantially horizontal direction. The nozzle 27 is mounted at the distal end of the arm 291. The arm 291 is connected to the rotary shaft 293. The rotary shaft 293 extends in a substantially vertical direction. The nozzle moving mechanism 295 turns the rotary shaft 293 about a rotation axis thereof extending in the substantially vertical direction to turn the arm 291 along a substantially horizontal plane. Accordingly, the nozzle 27 moves along the substantially horizontal plane. For example, the nozzle moving mechanism 295 includes an arm swinging motor that turns the rotary shaft 293 about the rotation axis. The arm swinging motor is a servomotor, for example. The nozzle moving mechanism 295 raises and lowers the rotary shaft 293 in the substantially vertical direction to raise and lower the arm 291. Accordingly, the nozzle 27 moves in the substantially vertical direction. For example, the nozzle moving mechanism 295 includes a ball screw mechanism and an arm lifting motor that applies drive power to the ball screw mechanism. The arm lifting motor is a servomotor, for example.

The pipe P1 supplies the processing liquid LQ to the nozzle 27. The valve V1 switches between supply start and supply stop of the processing liquid LQ to the nozzle 27.

The nozzle 30 supplies a rinsing liquid to the rotating substrate W after the substrate W is processed with the processing liquid LQ. Examples of the rinsing liquid includes deionized water, carbonated water, electrolytic ionized water, hydrogen water, ozone water, and hydrochloric acid water at diluted concentration (at 10 ppm to 100 ppm, for example). No particular limitations are placed on the type of the rinsing liquid so long as the rinsing liquid is capable of rinsing the substrate W.

The pipe P2 supplies the rinsing liquid to the nozzle 30. The valve V2 switches between supply start and supply stop of the rinsing liquid to the nozzle 30.

Preferably, the processing apparatuses each 200 further include a fluid supply unit 41, a unit operation section 43, a valve V3, a valve V4, a pipe P, a pipe P3, and a pipe P4. The chamber 21 accommodates the fluid supply unit 41, the unit operation section 43, and a part of the pipe P.

The fluid supply unit 41 is located above the spin chuck 23. The fluid supply unit 41 includes a blocking plate 411, a support shaft 413, and a nozzle 415.

The blocking plate 411 is substantially disk-shaped, for example. The diameter of the blocking plate 411 is substantially equal to the diameter of the substrate W, for example. However, the diameter of the blocking plate 411 may be slightly smaller or slightly larger than the diameter of the substrate W. The blocking plate 411 is disposed so that the lower surface of the blocking plate 411 is substantially horizontal. Furthermore, the blocking plate 411 is disposed so that the central axis of the blocking plate 411 coincides with the rotation axis AX2 of the spin chuck 2. The lower surface of the blocking plate 411 faces the substrate W held by the spin chuck 23. The blocking plate 411 is connected in a horizontal posture to the lower end of the support shaft 413.

The unit operation section 43 raises and lowers the fluid supply unit 41 between an adjacent point and a retraction point. The adjacent point refers to a point where the blocking plate 411 is lowered to be close to the substrate W with a predetermined interval left above the upper surface of the substrate W. The blocking plate 411 at the adjacent point covers the surface of the substrate W to block the surface of the substrate W from above. That is, the blocking plate 411 at the adjacent point faces the surface of the substrate W to cover the surface of the substrate W from above. The retraction point refers to a point located above the adjacent point and apart from the substrate W as a result of the blocking plate 411 being raised. FIG. 4 illustrates the blocking plate 411 at the retraction point. Furthermore, the unit operation section 43 at the adjacent point rotates the fluid supply unit 41. For example, the unit operation section 43 includes a ball screw mechanism and a lifting motor that applies driving power to the ball screw mechanism. The lifting motor is a servomotor, for example. For example, the unit operation section 43 includes a motor and a transmission mechanism that transmits the rotation of the motor to the fluid supply unit 41.

The nozzle 415 of the fluid supply unit 41 is disposed inside the blocking plate 411 and the support shaft 413. The distal end of the nozzle 415 is exposed at the lower surface of the blocking plate 411. The nozzle 415 is connected to the pipe P. The pipe P is connected to the pipe P3 via the valve V3. When the valve V3 is opened, a hydrophobizing agent is supplied to the nozzle 415. The pipe P is also connected to the pipe P4 via the valve V4. When the valve V4 is opened, an organic solvent is supplied to the nozzle 415.

When the valve V3 is opened with the fluid supply unit 41 positioned at the adjacent point, the nozzle 415 supplies the hydrophobizing agent to the structures 63 of the rotating substrate W. The nozzle 415 is equivalent to an example of a “hydrophobizing section”.

Specifically, the nozzle 415 supplies the hydrophobizing agent to the structures 63 to increase the hydrophobicity of the respective surfaces 62 of the structures 63 from that before supply of the hydrophobizing agent.

The hydrophobicity refers to the degree of difficulty with which a liquid adheres to the surface of a solid. The higher the hydrophobicity is, the more difficult it is for the liquid to adhere to the surface of the solid. That is, the higher the hydrophobicity is, the harder it is for the surface of the solid to get wet. The hydrophobicity can be represented by the contact angle CA. The narrower the contact angle CA is, the higher the hydrophobicity is. The wider the contact angle CA is, the smaller the surface tension of the solid is. The higher the hydrophobicity is, the smaller the surface tension of the solid is.

The hydrophobizing agent is a liquid, for example. The hydrophobizing agent is a silicon-based hydrophobizing agent or a metal-based hydrophobizing agent. The silicon-based hydrophobizing agent hydrophobizes silicon itself and a compound containing silicon. An example of the silicon-based hydrophobizing agent is a silane coupling agent. The silane coupling agent includes for example at least one of hexamethyldisilazane (HMDS), tetramethylsilane (TMS), fluorinated alkyl chlorosilane, alkyl disilazane, and a non-chlorohydrophobizing agent. The non-chlorinated hydrophobizing agent includes for example at least one of dimethylsilyldimethylamine, dimethylsilyldiethylamine, hexamethyldisilazane, tetramethyldisilazane, bis(dimethylamino)dimethylsilane, N,N-dimethylamino trimethylsilane, N-(trimethylsilyl)dimethylamine, and an organosilane compound. The metal-based hydrophobizing agent hydrophobizes its metal and a compound containing the metal. The metal-based hydrophobizing agent includes at least one of an organic silicon compound and amine having a hydrophobic group.

In particular, in the first embodiment, the nozzle 415 supplies, after the nozzle 27 supplies the processing liquid LQ to the structures 63 of the substrate W, the hydrophobizing agent to the structures 63 to increase the hydrophobicity of the respective surfaces 62 of the structures 63 from that before supply of the hydrophobizing agent. Therefore, the surface tension of the respective surfaces 62 of the structures 63 can be reduced in the first embodiment. As a result, collapse of the structures 63 due to the presence of surface tension of the structures 63 can be inhibited.

Note that the spin chuck 23 is rotated at high speed by the spin motor 25 to dry the substrate W after the hydrophobicity of the respective surfaces 62 of the structures 63 is increased using the nozzle 415. The spin chuck 23 corresponds to an example of a “drying section”.

In the following description, an increase in hydrophobicity of the respective surfaces 62 of the structures 63 from that before supply of the hydrophobizing agent is referred to as “hydrophobization”.

By contrast, when the valve V4 is opened with the fluid supply unit 41 positioned at the adjacent point, the nozzle 415 supplies the organic solvent to the structures 63 of the rotating substrate W. The organic solvent is a liquid, for example. The surface tension of the organic solvent is smaller than the surface tension of the rinsing liquid. Examples of the organic solvent include isopropyl alcohol (IPA) and hydrofluoroether (HFE). Specifically, after the rinsing liquid is supplied to the substrate W or the hydrophobizing agent is supplied to the substrate W, the nozzle 415 supplies the organic solvent to the substrate W.

The guards 49 each have a substantially cylindrical shape. Each of the guards 49 receives a liquid (the processing liquid LQ, the rinsing liquid, the hydrophobizing agent, or the organic solvent) discharged from the substrate W. Note that the type of the guards 49 depends on the types of the liquids discharged from the substrate W.

The processor of the controller U3 runs the computer programs stored in the storage device of the controller U3 to control each processing apparatus 200.

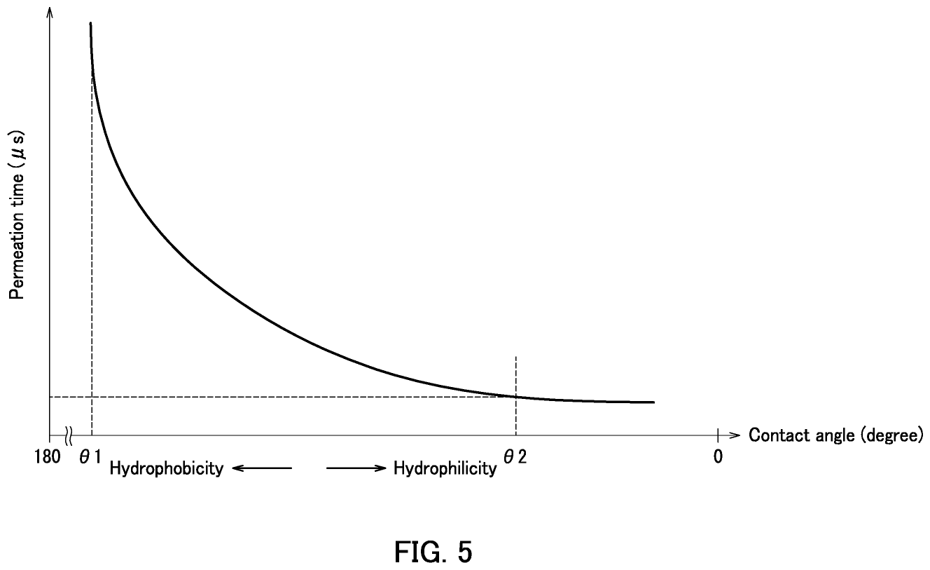

Preferable hydrophilicity of the pattern PT of the substrate W will be described next with reference to FIGS. 2A, 2B, and 5. FIG. 5 is a graph representation showing the relationship between permeation time and the contact angle CA of the processing liquid LQ. In FIG. 5, the vertical axis indicates the permeation time (μ second) of the processing liquid LQ permeating into the space SP between the structures 63 of the substrate W illustrated in FIG. 2A or 2B. Specifically, the permeation time is a time period from when the processing liquid LQ adheres to the structures 63 to when the processing liquid LQ infiltrates into the space SP and reaches the surface 61a or the vicinity of the surface 61a of the substrate body 61. The horizontal axis indicates the contact angle CA (degree) in descending order. The contact angle CA is an angle of the surface of the processing liquid LQ relative to the surface 62 of a structure 63.

As illustrated in FIG. 5, when the contact angle CA is θ1 or more, the processing liquid LQ does not permeate into the space SP between the structures 63. That is, 02 is a contact angle CA when the permeation time is infinite. For example, θ1 is 90 degrees. That is, when the contact angle CA is 90 degrees or more, the processing liquid LQ does not permeate into the space SP between the structures 63.

By contrast, when the contact angle CA is θ2 or less, the permeation time becomes substantially constant and is the shortest. As such, the hydrophilizing apparatus 1 preferably executes the predetermined processing on the structures 63 of the substrate W so that the structures 63 have hydrophilicity corresponding to the contact angle CA when the permeation time of the processing liquid LQ is substantially constant.

In the first embodiment, the ultraviolet irradiating section 3 of the hydrophilizing apparatus 1 preferably irradiates the structures 63 of the substrates with the ultraviolet rays so that the structures 63 have hydrophilicity corresponding to the contact angle CA when the permeation time of the processing liquid LQ is substantially constant.

A contact angle CA of θ2 is the widest contact angle CA of contact angles CA when the permeation time is substantially constant. Therefore, the hydrophilizing apparatus 1 preferably executes the predetermined processing on the structures 63 of the substrate W so that the contact angle CA is θ2 or less. In the first embodiment, the ultraviolet irradiating section 3 preferably irradiates the structures 63 of the substrate W with the ultraviolet rays so that the contact angle CA is θ2 or less. For example, when θ2 is 70 degrees, the permeation time is 1.1 μseconds.

For example, the contact angle CA is less than 90 degrees, preferably less than 70 degrees, and more preferably less than 50 degrees. Yet, the contact angle CA is still further preferably less than 30 degrees, more preferably less than 10 degrees, and still more preferably less than 5 degrees. This is because a narrower contact angle CA represents a higher hydrophilicity.

The structures 63 of the substrate W will be further described next with reference to FIGS. 2A and 2B. Preferably, a distance L between adjacent structures 63 of the structures 63 satisfies a prescribed condition (also referred to below as “prescribed condition PC”). The prescribed condition PC is that the same processing liquid as the processing liquid LQ is unable to permeate into the space SP between the adjacent structures 63 before the hydrophilicity of the respective surfaces 62 of the structures 63 is increased by the hydrophilizing apparatus 1 (i.e., before increasing the hydrophilicity). According to the first embodiment, even in a case in which the structures 63 are microstructures having such a small distance L that satisfies the prescribed condition PC, hydrophilization of the structures 63 can cause the processing liquid LQ to permeate into the space SP between the structures 63.

Preferably, the prescribed condition PC includes a first condition and a second condition. The first condition is that the same processing liquid as the processing liquid LQ is unable to permeate into the space SP between the adjacent structures 63 through the capillary action before the hydrophilicity of the respective surfaces 62 of the structures 63 is increased by the hydrophilizing apparatus 1 (i.e., before increasing the hydrophilicity). The second condition is that the processing liquid LQ is enabled to permeate into the space SP between the adjacent structures 63 through the capillary action after the hydrophilicity of the respective surfaces 62 of the structures 63 is increased by the hydrophilizing apparatus 1 (i.e., after increasing the hydrophilicity). Specifically, the second condition is that the processing liquid LQ is enabled to permeate into the space SP between the adjacent structures 63 through the capillary action in supply of the processing liquid LQ to the structures 36 (i.e., in supplying the processing liquid LQ) after the hydrophilicity of the respective surfaces 62 of the structures 63 is increased by the hydrophilizing apparatus 1 (i.e., after increasing the hydrophilicity).

According to the first embodiment, even in a case in which the structures 63 are microstructures having such a small distance L that satisfies the first condition, hydrophilization of the structures 63 can cause the processing liquid LQ to permeate into the space SP between the structures 63.

The distance L between adjacent structures 63 of the plurality of structures is 3 nm or shorter, for example. For example, as a result of the distance L being 3 nm or shorter, the prescribed condition PC (including the first condition and the second condition) is satisfied. The structures 63 each have a length H of at least 0.02 μm and no greater than 0.1 μm, for example. The length H is a length in the first direction D1. The pattern PT has an aspect ratio of at least 6 and no greater than 100, for example. The aspect ratio is a ratio of the length H to the distance L. Furthermore, the processing liquid LQ has a viscosity of at least 1 centipores (cP) and no greater than 70 cP, for example.

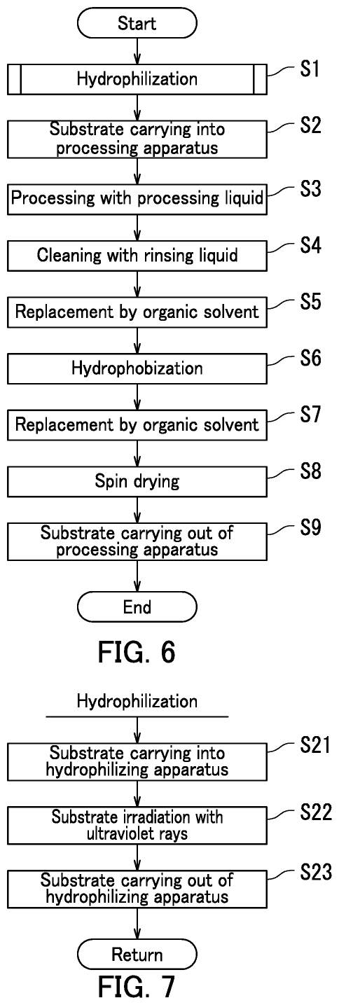

The following describes a substrate processing method according to the first embodiment with reference to FIGS. 3, 4, 6, and 7. The substrate processing apparatus 100 performs the substrate processing method. In the substrate processing method, the substrate W with the pattern PT including the structures 63 is processed. FIG. 6 is a flowchart depicting the substrate processing method. As depicted in FIG. 6, the substrate processing method includes Steps S1 to S9. Steps S1 to S9 are executed under control by the controller U3.

As illustrated in FIGS. 3 and 6, in Step S1, the hydrophilizing apparatus 1 executes the predetermined processing on the structures 63 of the substrate W with the non-liquid substance for a specific time period to increase the hydrophilicity of the respective surfaces 62 of the structures 63 from that before execution of the predetermined processing. Specifically, details of Step S1 are depicted in FIG. 7.

FIG. 7 is a flowchart depicting Step S1. As depicted in FIG. 7, Step S1 includes Steps S21 to S23.

In Step S21, the transport robot CR carries the substrate W into the hydrophilizing apparatus 1. The substrate holding section 5 then holds the substrate W. Furthermore, the rotary mechanism 15 drives the substrate holding section 5 so that the substrate holding section 5 starts rotating the substrate W.

In Step S22, the ultraviolet irradiating section 3 irradiates the structures 63 of the substrate W with the ultraviolet rays for a specific time period to increase the hydrophilicity of the respective surfaces 62 of the structures 63 from that before irradiation with the ultraviolet rays. Then, the rotary mechanism 15 stops the substrate holding section 5 so that the substrate holding section 5 stops rotating the substrate W.

In Step S23, the transport robot CR carries the substrate W out of the hydrophilizing apparatus 1. Then, the hydrophilizing process is completed and the processing returns to the main routine depicted in FIG. 6 and proceeds to Step S2.

As illustrated in FIGS. 4 and 6, next in Step S2, the transport robot CR carries the substrate W into one of the processing apparatuses 200. The spin chuck 23 then holds the substrate W. Subsequently, the spin motor 25 drives the spin chuck 23 so that the spin chuck 23 starts rotating the substrate W.

Next, in Step S3, the nozzle 27 supplies the processing liquid LQ to the structures 63 of the substrate W. That is, the nozzle 27 supplies the processing liquid LQ to the structures 63 in Step S3 after increasing the hydrophilicity in Step S1 and after Step S2. As a result, the substrate W is processed with the processing liquid LQ.

Next, in Step S4, the nozzle 30 supplies the rinsing liquid to the substrate W. As a result, the rinsing liquid rinses away the processing liquid LQ on the substrate W and the substrate W is thus cleaned.

Next, in Step S5, the nozzle 415 supplies the organic solvent to the substrate W. As a result, the rinsing liquid adhering to the substrate W is replaced by the organic solvent. In Step S5, the valve V4 is opened while the valve V3 is closed.

Next, in Step S6, the nozzle 415 supplies the hydrophobizing agent to the substrate W. As a result, the substrate W is hydrophobized. That is, after supplying the processing liquid LQ in Step S3 and after Steps S4 and S5, the nozzle 415 supplies the hydrophobizing agent to the structures 63 of the substrate W to increase the hydrophobicity of the respective surfaces 62 of the structures 63 from that before supply of the hydrophobizing agent in Step S6. In Step S3, the valve V3 is opened while the valve V4 is closed.

Next, in Step S7, the nozzle 415 supplies the organic solvent to the substrate W. As a result, the hydrophobizing agent adhering to the substrate W is replaced by the organic solvent. In Step S7, the valve V4 is opened while the valve V3 is closed.

Next, in Step S8, the spin motor 25 drives the spin chuck 23 to increase the rotational speed of the spin chuck to a high rotational speed and keeps the rotational speed of the spin chuck 23 at the high rotational speed. As a result, the substrate W is rotated at the high rotational speed so that the organic solvent adhering to the substrate W is shaken off, thereby drying the substrate W. That is, the substrate W is dried in Step S8 after increasing the hydrophobicity in Step S6 and after Step S7. When Step S8 is executed for a specific time period, the spin motor 25 stops to stop the rotation of the spin chuck 23. As a result, the substrate W is stopped. Note that the high rotational speed is higher than the rotational speed of the spin chuck 23 in Steps S3 and S4.

Next, in Step S9, the transport robot CR carries the substrate W out of the processing apparatus 200. The processing then ends.

In the substrate processing method according to the first embodiment, the structures 63 of the substrate W are hydrophilized before the processing with the processing liquid LQ as has been described with reference to FIGS. 6 and 7. Therefore, infiltration of the processing liquid LQ into the space SP between the structures 63 can be promoted. As a result, the processing liquid LQ quickly permeates into the space SP between the structures 63, thereby achieving effective processing of the structures 63 with the processing liquid LQ. For example, in a case in which the processing liquid LQ is an etching solution, the etching solution quickly permeates into the space SP between the structures 63, thereby achieving effective etching of the structures 63.

Furthermore, in the semiconductor production method according to the first embodiment, a semiconductor substrate W with the pattern PT including the structures 63 is processed according to the substrate processing method including Steps S1 to S9 to produce a semiconductor that is the processed semiconductor substrate W.

Note that the substrate processing method and the semiconductor production method may not include Steps S5 to S7.

### (Variation)

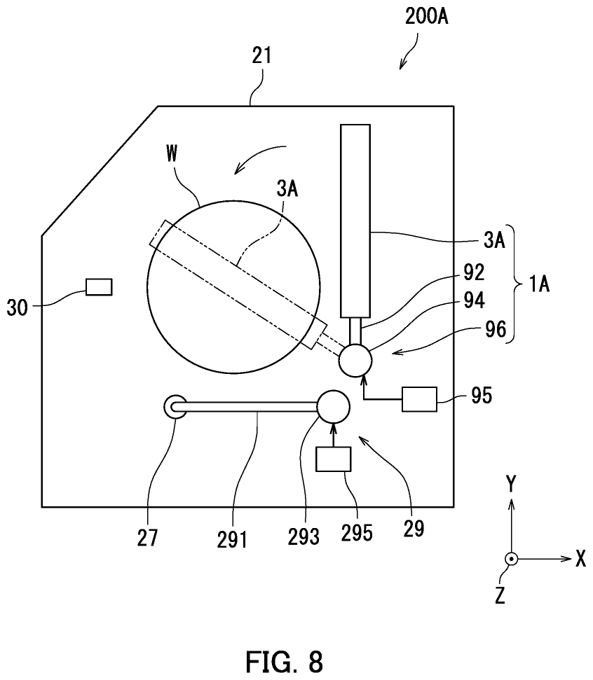

The following describes a substrate processing apparatus 100 according to a variation of the first embodiment of the present invention with reference to FIG. 8. The variation differs from the first embodiment described with reference to FIGS. 1 to 7 in that a hydrophilizing apparatus 1A is mounted in each of processing apparatuses 200A. The following mainly describes the differences of the variation from the first embodiment.

FIG. 8 is a schematic plan view of the hydrophilizing apparatus 1A of a processing apparatus 200A according to the variation. As illustrated in FIG. 7, the processing apparatus 200A includes a hydrophilizing apparatus 1A in addition to the components of the processing apparatus 200 illustrated in FIG. 4. Note that in the variation, the substrate processing apparatus 100 as illustrated in FIG. 1 does not include the hydrophilizing apparatus 1 illustrated in FIG. 3.

Before the processing liquid LQ is supplied to the substrate W, the hydrophilizing apparatus 1A executes the predetermined processing with the non-liquid substance on the structures 63 of the substrate W to increase the hydrophilicity of the respective surfaces 62 of the structures 63 from that before execution of the predetermined processing. Therefore, in the variation, permeation of the processing liquid LQ into the space SP between the structures 63 can be promoted likewise in the first embodiment, thereby achieving effective permeation of the processing liquid LQ into the space SP. As a result, the structures 63 can be processed effectively.

Specifically, the hydrophilizing apparatus 1A includes an ultraviolet irradiating section 3A and a moving section 9. The ultraviolet irradiating section 3A emits ultraviolet rays. The ultraviolet irradiating section 3A includes for example a lamp that emits the ultraviolet rays or a light emitting diodes that emit the ultraviolet rays. The ultraviolet irradiating section 3A extends in a specific direction. The length of the ultraviolet irradiating section 3A in the longitudinal direction thereof is for example substantially equal to the diameter of the substrate W or substantially equal to the radius of the substrate W.

Before the processing liquid LQ is supplied to the substrate W, the ultraviolet irradiating section 3A irradiates the surfaces 62 of the structures 63 of the rotating substrate W with the ultraviolet rays to increase the hydrophilicity of the respective surfaces 62 of the structures 63 from that before irradiation with the ultraviolet rays. In the variation, as a result of irradiation with the ultraviolet rays with an energy larger than that of visible light, the surfaces 62 of the structures 63 can be hydrophilized effectively.

The moving section 9 moves the ultraviolet irradiating section 3A between a processing point and a retraction point. The processing point refers to a point located above the substrate W. The ultraviolet irradiating section 3A at the processing point irradiates the surfaces 62 of the structure 63 of the substrate W with the ultraviolet rays. The retraction point refers to a point located outward of the substrate W in the radial direction of the substrate W. Specifically, the moving section 9 includes an arm 92, a rotary shaft 94, and a moving mechanism 96. The ultraviolet irradiating section 3A is mounted on the arm 92. The arm 92 is driven by the rotary shaft 94 and the moving mechanism 96 to be turned along a substantially horizontal plane or to be raised and lowered in a substantially vertical direction. Besides this, the configurations of the arm 92, the rotary shaft 94, and the moving mechanism 96 are respectively the same as the configurations of the arm 291, the rotary shaft 293, and the nozzle moving mechanism 295 illustrated in FIG. 4.

With reference to FIGS. 6 to 8, a substrate processing method and a semiconductor production method according to the variation will be described next. The substrate processing method and the semiconductor production method according to the variation are respectively similar to the substrate processing method and the semiconductor production method according to the first embodiment depicted in FIGS. 6 and 7. However, the following are the differences of the variation from the first embodiment.

That is, in Step S21 in FIG. 7, the transport robot CR carries the substrate W into the processing apparatus 200A. Rotation of the substrate W is then started.

Next, in Step S22, the ultraviolet irradiating section 3A illustrated in FIG. 8 irradiates the structures 63 of the rotating substrate W with the ultraviolet rays for a specific time period to increase the hydrophilicity of the respective surfaces 62 of the structures 63 from that before irradiation with the ultraviolet rays. Rotation of the substrate W is then stopped.

In the variation, Step S23 is not executed. Accordingly, when Step S22 is completed, the processing returns to the main routine depicted in FIG. 6. In this case of the variation, Step S2 is not executed and the processing proceeds to Step S4.

As has been described with reference to FIGS. 6 to 8, Step S3 to S8 are executed in the processing apparatus 200A in the variation. Therefore, the substrate W need not be carried out of the processing apparatus 200A for hydrophilization of the substrate W. This can increase throughput in implementation of the substrate processing method and the semiconductor production method.

Note that the substrate processing method and the semiconductor production method in the variation may not include Steps S5 to S7.

### Second Embodiment

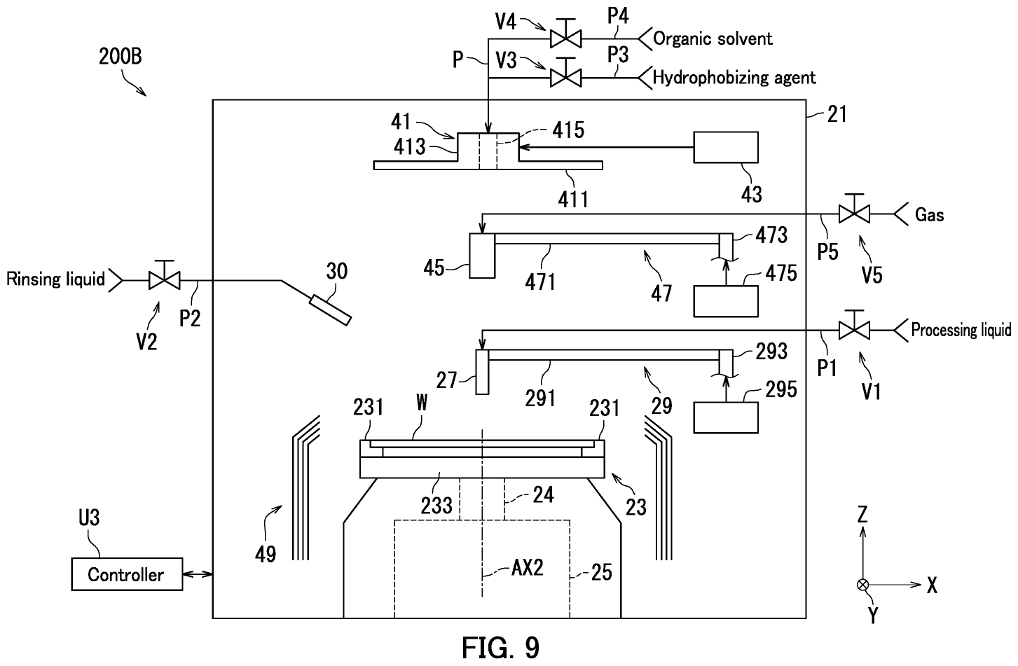

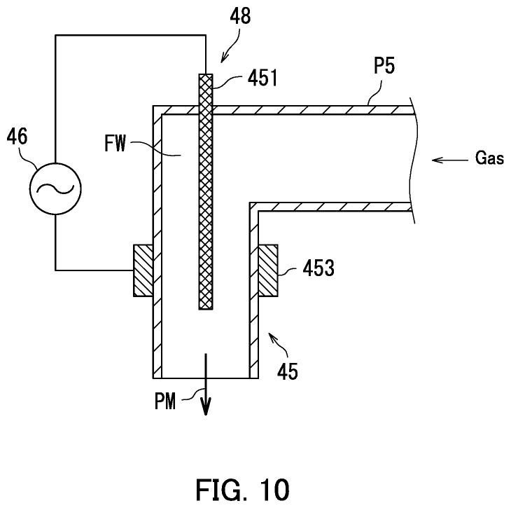

The following describes a substrate processing apparatus 100 according to a second embodiment of the present invention with reference to FIGS. 9 and 10. The second embodiment differs from the first embodiment mainly in that each of processing apparatuses 200B in the second embodiment irradiates the substrate W with plasma to hydrophilize the substrate W. The following mainly describes the differences of the second embodiment from the first embodiment.

FIG. 9 is a schematic cross-sectional view of the processing apparatus 200B according to the second embodiment. As illustrated in FIG. 9, the processing apparatus 200B includes a hydrophilizing nozzle 45, a nozzle moving section 47, a pipe P5, and a valve V5 in addition to the components of the processing apparatus 200 illustrated in FIG. 4. Note that in the second embodiment, the substrate processing apparatus 100 as illustrated in FIG. 1 does not include the hydrophilizing apparatus 1 illustrated in FIG. 2.

A gas is supplied to the hydrophilizing nozzle 45 through the pipe P5. The valve V5 switches between supply start and supply stop of a gas to the hydrophilizing nozzle 45. Examples of the gas include air, inert gases, and oxygen. Examples of the inert gases include nitrogen, argon, and helium. Note that no particular limitations are placed on the type of the gas so long as plasma can be generated from the gas.

Before the processing liquid LQ is supplied to the substrate W, the hydrophilizing nozzle 45 executes predetermined processing with a non-liquid substance on the structures 63 of the substrate W to increase the hydrophilicity of the respective surfaces of the structures 63 from that before execution of the predetermined processing. Therefore, in the second embodiment, infiltration of the processing liquid LQ into the space SP between the structures 63 can be promoted likewise in the first embodiment, thereby achieving effective permeation of the processing liquid LQ into the space SP. As a result, the structures 63 can be effectively processed with the processing liquid LQ. Besides this, the second embodiment can bring effects similar to those in the first embodiment. The hydrophilizing nozzle 45 corresponds to an example of the “hydrophilizing section”.

The predetermined processing in the second embodiment is processing to irradiate the structures 63 with plasma. Note that in the second embodiment, the substrate W is dried before the predetermined processing, for example.

Specifically, the hydrophilizing nozzle 45 emits plasma. That is, the hydrophilizing nozzle 45 generates plasma by electrolytically dissociating the gas supplied through the pipe P5 and emits the generated plasma together with the gas. In other words, the hydrophilizing nozzle 45 emits the plasma along with a gas flow. In yet other words, the hydrophilizing nozzle 45 generates and emits a plasma flow.

More specifically, before the processing liquid LQ is supplied to the substrate W, the hydrophilizing nozzle 45 irradiates the surfaces 62 of the structures 63 of the rotating substrate W with plasma to increase the hydrophilicity of the respective surfaces 62 of the structures 63 from that before plasma irradiation. Presumably, the reason for the increase in the hydrophilicity is that plasma irradiation promotes oxidation of the surfaces 62 of the structures 63. According to the second embodiment, plasma irradiation can achieve effective hydrophilization of the surfaces 62 of the structures 63.

The nozzle moving section 47 moves the hydrophilizing nozzle 45 between a processing point and a retraction point. The processing point refers to a point located above the substrate W. The hydrophilizing nozzle 45 at the processing point irradiates the surfaces 62 of the structures 63 of the substrate W with the plasma. The retraction point refers to a point located outward of the substrate W in the radial direction of the substrate W. Specifically, the nozzle moving section 47 includes an arm 471, a rotary shaft 473, and a moving mechanism 475. The hydrophilizing nozzle 45 is mounted on the distal end of the arm 471. The arm 471 is driven by the rotary shaft 473 and the moving mechanism 475 to be turned along a substantially horizontal plane or to be raised and lowered in a substantially vertical direction. Besides this, the configurations of the arm 471, the rotary shaft 473, and the moving mechanism 475 are respectively the same as the configurations of the arm 291, the rotary shaft 293, and the nozzle moving mechanism 295 illustrated in FIG. 4.

Next, the hydrophilizing nozzle 45 will be described in detail with reference to FIG. 10. FIG. 10 is a cross-sectional view of the hydrophilizing nozzle 45. As illustrated in FIG. 10, the hydrophilizing nozzle 45 includes a first electrode 451 and a second electrode 453. The first electrode 451 is substantially columnar in shape. The first electrode 451 is disposed in a flow channel FW within the hydrophilizing nozzle 45. A gas is supplied to the flow channel FW through the pipe P5. The second electrode 453 is substantially cylindrical in shape. The second electrode 453 is disposed around the outer circumferential surface of the hydrophilizing nozzle 45.

The processing apparatus 200B further includes an alternating current power source 46. The alternating current power source 46 applies an alternating current voltage across the first electrode 451 and the second electrode 453. As a result, the gas supplied through the pipe P5 is electrolytically dissociated to generate plasma PM. The plasma PM is emitted from the hydrophilizing nozzle 45 together with the gas. The plasma PM is atmospheric pressure plasma, for example. The atmospheric pressure plasma is plasma generated under atmospheric pressure. The first electrode 451, the second electrode 453, and the alternating current power source 46 constitute a plasma generator 48. Note that no particular limitations are placed on the configuration of the plasma generator 48 so long as the plasma generator 78 is capable of generating plasma. Also, no particular limitations are placed on the location of the plasma generator 48 so long as the location enables the plasma generator 48 to emit the plasma to the substrate W.

Each of the first electrode 451 and the second electrode 453 is formed of a resin containing carbon, for example. The carbon forms a carbon nanotube, for example. The resin is a fluororesin, for example. Examples of the fluororesin include polytetrafluoroethylene(tetrafluoro) and polychlorotrifluoroethylene(trifluoro). As a result of the first electrode 451 and the second electrode 453 being formed as above, chemical resistance can be increased while ensuring conductivity.

With reference to FIGS. 6, 7, and 9, a substrate processing method and a semiconductor production method according to the second embodiment will be described next. The substrate processing method and the semiconductor production method according to the second embodiment are respectively similar to the substrate processing method and the semiconductor production method according to the first embodiment illustrated in FIGS. 6 and 7. However, the following are the differences of the second embodiment from the first embodiment.

That is, the transport robot CR carries the substrate W into the processing apparatus 200A in Step S21 of FIG. 7. Rotation of the substrate W is then started.

Next, in Step S22, the hydrophilizing nozzle 45 illustrated in FIG. 9 irradiates the structures 63 of the substrate W with the plasma for a specific time period to increase the hydrophilicity of the respective surfaces 62 of the structures 63 from that before plasma irradiation. The rotation of the substrate W is then stopped.

Note that the hydrophilizing nozzle 45 preferably irradiates the structures 63 of the substrate W with the plasma so that the structures 63 have hydrophilicity corresponding to the contact angle CA when the permeation time of the processing liquid LQ is substantially constant (FIG. 5). That is, the hydrophilizing nozzle 45 preferably irradiates the structures 63 of the substrate W with the plasma so that the contact angle CA is θ2 or less (FIG. 5).

Step S23 is not executed in the second embodiment. Accordingly, when Step S22 is completed, the processing returns to the main routine depicted in FIG. 6. In this case of the second embodiment, Step S2 is not executed and the processing proceeds to Step S4.

As has been described with reference to FIGS. 6, 7, and 9, Steps S3 to S8 are executed in the processing apparatus 200B in the second embodiment. Therefore, the substrate W need not be carried out of the processing apparatus 200B for hydrophilization of the substrate W. As a result, throughput can be increased in implementing the substrate processing method and the semiconductor production method.

Note that the substrate processing method and the semiconductor production method in the second embodiment may not include Steps S5 to S7.

### Third Embodiment

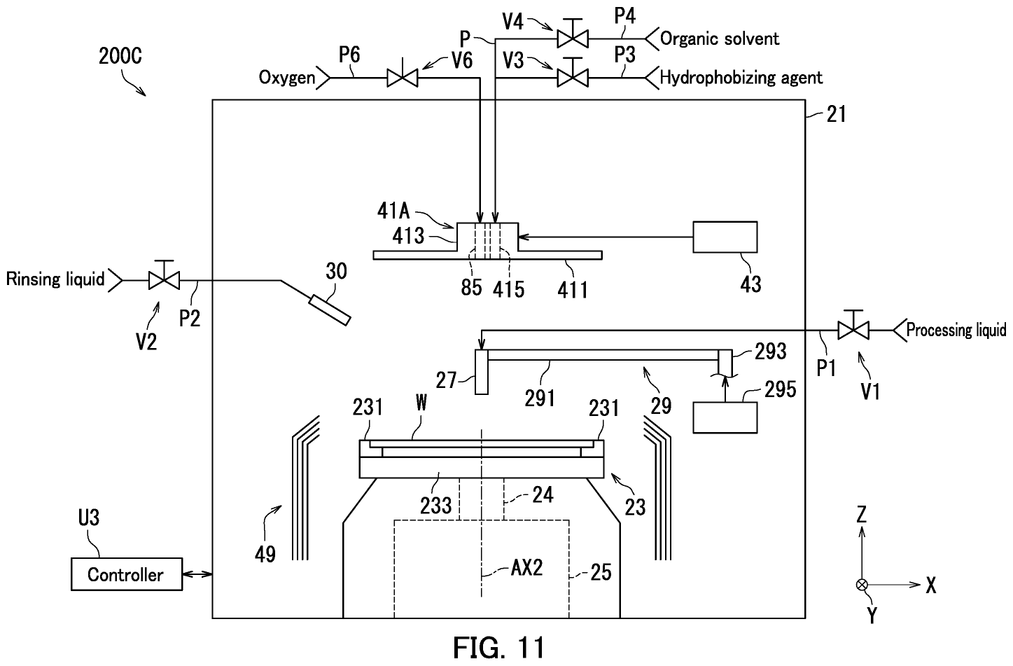

The following describes a substrate processing apparatus 100 according to a third embodiment of the present invention with reference to FIG. 11. The third embodiment differs from the second embodiment mainly in that processing apparatuses 200C in the third embodiment irradiates the substrate W with oxygen or an allotrope of oxygen to hydrophilize the substrate W. The following mainly describes the differences of the third embodiment from the second embodiment.

FIG. 11 is a schematic cross-sectional view of a processing apparatus 200C according to the third embodiment. As illustrated in FIG. 11, the processing apparatus 200C includes a hydrophilizing nozzle 85, a pipe P6, and a valve V6 in place of the hydrophilizing nozzle 45, the nozzle moving section 47, the pipe P5, and the valve V5 of the processing apparatus 200B illustrated in FIG. 9. Specifically, a fluid supply unit 41A includes the hydrophilizing nozzle 85. The hydrophilizing nozzle 85 is disposed inside the blocking plate 411 and the support shaft 413. The distal end of the hydrophilizing nozzle 85 is exposed from the lower surface of the blocking plate 411.

The pipe P6 is connected to the hydrophilizing nozzle 85. The valve V6 switches between supply start and supply stop of oxygen to the hydrophilizing nozzle 85. When the valve V6 is opened, oxygen (02) or an allotrope of oxygen is supplied to the hydrophilizing nozzle 85. Note that the gas supplied to the hydrophilizing nozzle 85 through the pipe P6 is not limited to oxygen and may be an allotrope of oxygen. An example of the allotrope of oxygen is ozone (03). Note that no particular limitations are placed on the allotrope of oxygen so long as the surfaces 62 of the structures 63 of the substrate W can be oxidized.

Before the processing liquid LQ is supplied to substrate W, the hydrophilizing nozzle 85 executes predetermined processing with a non-liquid substance on the structures 63 of the substrate W to increase the hydrophilicity of the respective surfaces 62 of the structures 63 from that before execution of the predetermined processing. Accordingly, in the third embodiment likewise in the second embodiment, infiltration of the processing liquid LQ into the space SP between the structures 63 can be promoted, thereby achieving effective permeation of the processing liquid LQ into the space SP. As a result, the structures 63 can be effectively processed with the processing liquid LQ. Besides this, the third embodiment can bring effects similar to those in the second embodiment. The hydrophilizing nozzle 85 corresponds to an example of the “hydrophilizing section”.

The predetermined processing in the third embodiment is processing to supply oxygen or an allotrope of oxygen to the structures 63. Note that in the third embodiment, the substrate W is dried before execution of the predetermined processing, for example.

Specifically, before the processing liquid LQ is supplied to the substrate W, the hydrophilizing nozzle 85 supplies oxygen or an allotrope of oxygen to the surfaces 62 of the structures 63 of the rotating substrate W to increase the hydrophilicity of the respective surfaces 62 of the structures 63 from that before supply of oxygen or the allotrope of oxygen. Presumably, a reason for the increase in the hydrophilicity is that exposure of the surfaces 62 of the structures 63 to oxygen or the allotrope of oxygen through supply of oxygen or the allotrope of oxygen promotes oxidization of the surfaces 62 of the structures 63. According to the third embodiment, supply of oxygen or an allotrope of oxygen can achieve effective hydrophilization of the surfaces 62 of the structures 63.

Once the valve V6 is opened when the fluid supply unit 41A is lowered so that the hydrophilizing nozzle 85 is located at the adjacent point, the hydrophilizing nozzle 85 supplies oxygen or the allotrope of oxygen to the structures 63 of the rotating substrate W. The blocking plate 411 is located over the substrate W. This allows sufficient exposure of the structures 63 to oxygen or the allotrope of oxygen. As a result, the surfaces 62 of the structures 63 can be effectively hydrophilized.

With reference to FIGS. 6, 7, and 11, a substrate processing method and a semiconductor production method according to the third embodiment will be described next. The substrate processing method and the semiconductor production method according to the third embodiment are respectively the same as the substrate processing method and the semiconductor production method according to the second embodiment described with reference to FIGS. 6 and 7. However, the following are the differences of the third embodiment from the second embodiment.

That is, in Step S22 of FIG. 7, the hydrophilizing nozzle 85 illustrated in FIG. 11 supplies oxygen or the allotrope of oxygen to the structures 63 of the substrate W for a specific time period to increase the hydrophilicity of the respective surfaces 62 of the structures 63 from that before supply of oxygen or the allotrope of oxygen.

Note that the hydrophilizing nozzle 85 preferably supplies oxygen or the allotrope of oxygen to the structures 63 of the substrate W so that the structures 63 have hydrophilicity corresponding to the contact angle CA when the permeation time of the processing liquid LQ is substantially constant (FIG. 5). That is, the hydrophilizing nozzle 85 preferably supplies oxygen or the allotrope of oxygen to the structures 63 of the substrate W so that the contact angle CA is θ2 or less.

### Fourth Embodiment

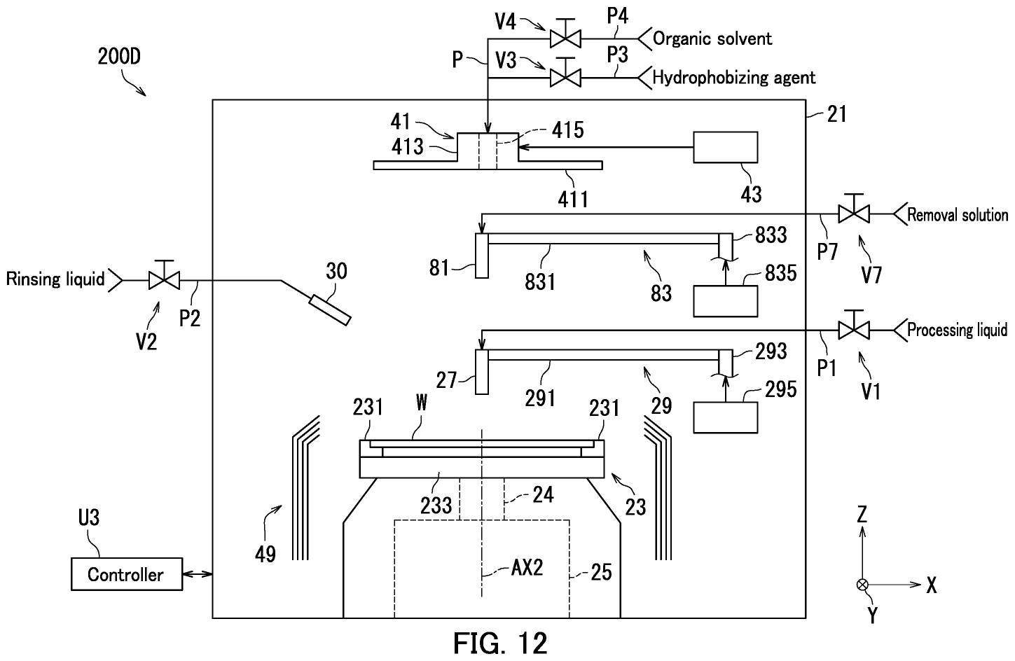

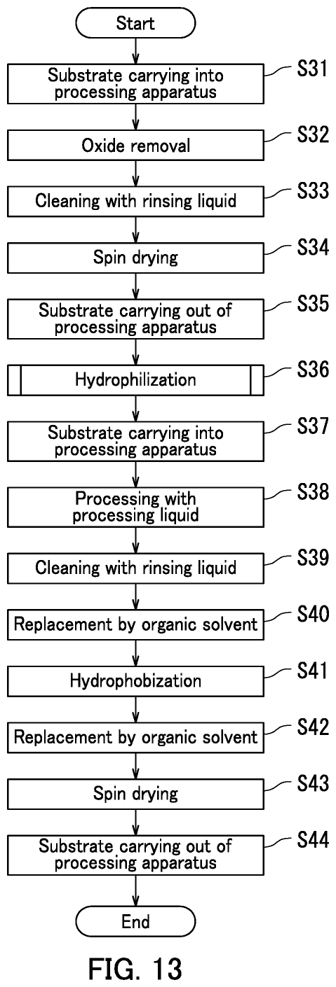

The following describes a substrate processing apparatus 100 according to a fourth embodiment of the present invention with reference to FIGS. 12 and 13. The fourth embodiment differs from the first embodiment mainly in that processing apparatuses 200D remove oxide from the substrate W. The following mainly describes the differences of the fourth embodiment from the first embodiment.

FIG. 12 is a schematic cross-sectional view of a processing apparatus 200D according to the fourth embodiment. As illustrated in FIG. 12, each processing apparatus 200D includes a nozzle 81, a nozzle moving section 83, a pipe P7, and a valve V7 in addition to the components of the processing apparatus 200 illustrated in FIG. 4. Note that in the fourth embodiment, the substrate processing apparatus 100 illustrated in FIG. 1 does not include the hydrophilizing apparatus 1 illustrated in FIG. 2.

The pipe P7 supplies a removal liquid to the nozzle 81. The valve V7 switches between supply start and supply stop of the removal liquid to the nozzle 81.

The removal liquid removes oxide from the substrate W. For example, the removal liquid removes oxide formed on the surfaces 62 of the structures 63 of the substrate W. The removal liquid removes a silicon oxide film from the substrate W, for example. The silicon oxide film is a natural oxide film, for example. The removal liquid is a chemical solution, for example. Examples of the chemical solution include hydrofluoric acid (HF), dilute hydrofluoric acid (DHF), and buffered hydrofluoric acid (BHF). Note that no particular limitations are placed on the type of the removal liquid so long as the removal liquid is capable of removing oxide from the substrate W.

The removal liquid differs from the processing liquid LQ. In the fourth embodiment, the processing liquid LQ is an etching solution, for example. Examples of the etching solution include organic alkalis (e.g., tetramethyl ammonium hydroxide (TMAH) and an ammonia hydrogen peroxide mixture (SC1). Note that no particular limitations are placed on the type of the etching solution so long as the etching solution is capable of etching the substrate W.

The nozzle 81 supplies the removal liquid for removing oxide from the substrate W to the substrate W before the hydrophilicity of the respective surfaces 62 of the structures 63 of the substrate W is increased. The nozzle 81 corresponds to an example of a “removal liquid supply section”.

The nozzle moving section 83 moves the nozzle 81 between a processing point and a retraction point. The processing point refers to a point located above the substrate W. The nozzle 81 at the processing point supplies the removal liquid to the surfaces 62 of the structures 63 of the substrate W. The retraction point refers to a point located outward of the substrate W in the radial direction of the substrate W. Specifically, the nozzle moving section 83 includes an arm 831, a rotary shaft 833, and a moving mechanism 835. The nozzle 81 is mounted at the distal end of the arm 831. The arm 831 is driven by the rotary shaft 833 and the moving mechanism 835 to be turned along a substantially horizontal plane or to be raised and lowered in a substantially vertical direction. Besides this, the configurations of the arm 831, the rotary shaft 833, and the moving mechanism 835 are respectively the same as the configurations of the arm 291, the rotary shaft 293, and the nozzle moving mechanism 295 illustrated in FIG. 4.

With reference to FIGS. 12 and 13, a substrate processing method according to the third embodiment will be described next. The substrate processing apparatus 100 implements the substrate processing method. FIG. 13 is a flowchart depicting the substrate processing method. As depicted in FIG. 13, the substrate processing method includes Steps S31 to S44. Steps S31 to S44 are executed under control by the controller U3.

As illustrated in FIGS. 12 and 13, the transport robot CR carries the substrate W into the processing apparatus 200D in Step S31. The rotation of the substrate W is then started.

Next, in Step S32, the nozzle 81 supplies the removal liquid to the substrate W. Specifically, the removal liquid for removing oxide formed on the surfaces 62 of the structures 63 is supplied to the substrate W before increasing the hydrophilicity in Step S36 and before Steps S33 to S35. As a result, the oxide is removed from the substrate W.

Next, in Step S33, the nozzle 30 supplies the rinsing liquid to the substrate W. As a result, the rinsing liquid rinses away the removal liquid on the substrate W and the substrate W is thus cleaned.

Next, in Step S34, the spin motor 25 drives the spin chuck 23 to increase the rotational speed of the spin chuck 23 to a high rotational speed and keeps the rotational speed of the spin chuck 23 at the high rotational speed. As a result, the substrate W is rotated at the high rotational speed so that the rinsing liquid adhering to the substrate W is shaken off, thereby cleaning the substrate W. When Step S34 is executed for a specific time period, the spin motor 25 stops to stop the rotation of the spin chuck 23. As a result, the substrate W is stopped. Note that the high rotational speed is higher than the rotational speed of the spin chuck 23 in Steps S32 and S33.

Next, in Step S35, the transport robot CR carries the substrate W out of the processing apparatus 200D.

Next, Steps S36 to S44 are executed. Steps S36 to S44 are respectively the same as Steps S1 to S9 in FIG. 6, and therefore description thereof is omitted.

As has been described with reference to FIGS. 12 and 13, the substrate processing apparatus 100 according to the fourth embodiment hydrophilizes the structures 63 of the substrate W before the processing with the processing liquid LQ. This can promote infiltration of the processing liquid LQ into the space SP between the structures 63. As a result, the processing liquid LQ quickly permeates into the space SP between the structures 63, thereby achieving effective processing of the structures 63 with the processing liquid LQ.

In particular, as a result of removal of oxide from the substrate W in Step S32, the hydrophobicity of the substrate W may be high after completion of Step S32. In view of the foregoing, the substrate W is hydrophilized in Step S36. This can achieve effective permeation of the processing liquid LQ into the space SP between the structures 63. Besides this, the fourth embodiment can bring effects similar to those in the first embodiment.

Here, it is possible that a liquid (e.g., the removal liquid or the rinsing liquid) adheres to a part of the substrate W while another part of the substrate W is dried, for example. Specifically, it is possible that the rinsing liquid adheres to a part of the substrate W while another part of the substrate W is dried after spin drying in Step S34. Further specifically, it is possible that after spin drying in Step S34, the rinsing liquid remains in the space SP between the structures 63 in an area close to the center of the substrate W while being thoroughly removed from the space SP in an area close to the outer edge of the substrate W. In this case, it is possible that the rinsing liquid remaining in the space SP is replaced by the processing liquid LQ and the processing liquid LQ permeates into the space SP in the area close to the center of the substrate W, whereas the processing liquid LQ has difficulty in permeating into the space SP in the area close to the outer edge of the substrate W. In view of the foregoing, in the fourth embodiment, the surfaces 62 of the structures 63 of the substrate W are hydrophilized in Step S36, thereby achieving quick and substantially uniform permeation of the processing liquid LQ into the space SP between the structures 63 over the entire substrate W. As a result, unevenness in results of the processing on the structures 63 with the processing liquid LQ can be reduced from occurring. For example, in a case in which the processing liquid LQ is an etching solution, unevenness in results of etching on the structures 63 can be reduced from occurring.

Furthermore, in the semiconductor production method according to the fourth embodiment, a semiconductor substrate W with a pattern PT including a plurality of structures 63 is processed according to the substrate processing method including Steps S31 to S44 to produce a semiconductor that is the processed semiconductor substrate W.

Note that the substrate processing method and the semiconductor production method may not include Steps S40 to S42.

Embodiments of the present invention have been described so far with reference to the accompanying drawings. However, the present invention is not limited to the above embodiments and can be practiced in various manners within a scope not departing from the gist of the present invention. Furthermore, the elements of configuration disclosed in the above embodiments may be altered as appropriate. For example, some of the elements of configuration indicated in some embodiment may be added to the elements of configuration indicated in another embodiment. Alternately or additionally, some of the elements of configuration indicated in some embodiment may be removed from the embodiment.

The drawings schematically illustrate elements of configuration in order to facilitate understanding of the invention and aspects of elements of configuration illustrated in the drawings, such as thickness, length, number, and interval thereof, may differ from actual aspects thereof in order to facilitate preparation of the drawings. Also, elements of configuration indicated in the above embodiments are merely examples and should not be taken as specific limitations. It is needless to say that various alterations may be made within a scope not substantially departing from the effects of the present invention.

(1) In the fourth embodiment described with reference to FIGS. 12 and 13, the processing apparatus 200D may include the hydrophilizing apparatus 1A in the variation of the first embodiment described with reference to FIG. 8.

(2) The processing apparatus 200D in the fourth embodiment may include the hydrophilizing nozzle 45, the nozzle moving section 47, the pipe P5, and the valve V5 in the second embodiment described with reference to FIG. 9.

(3) The processing apparatus 200D in the fourth embodiment may include the hydrophilizing nozzle 85, the pipe P6, and the valve V6 in the third embodiment described with reference to FIG. 11.

### INDUSTRIAL APPLICABILITY

The present invention relates to a substrate processing method, a semiconductor producing method, and a substrate processing apparatus, and has industrial applicability.

### REFERENCE SINGS LIST

1, 1A Hydrophilizing apparatus (hydrophilizing section)
23 Spin chuck (drying section)
27 Nozzle (processing liquid supply section)
45, 85 Hydrophilizing nozzle (hydrophilizing section)
81 Nozzle (removal liquid supply section)
415 Nozzle (hydrophobizing section)
100 Substrate processing apparatus
W Substrate

1. A substrate processing method for processing a substrate with a pattern including a plurality of structures, the method comprising:
increasing hydrophilicity of respective surfaces of the structures, by executing predetermined processing on the structures with a non-liquid substance, from that before execution of the predetermined processing; and
supplying a processing liquid to the structures after the increasing hydrophilicity.

2. The substrate processing method according to claim 1, further comprising
supplying a removal liquid for removing oxide from the substrate to the structures before the increasing hydrophilicity.

3. The substrate processing method according to claim 1, wherein
the predetermined processing is processing to irradiate the structures with ultraviolet rays.

4. The substrate processing method according to claim 1, wherein
the predetermined processing is processing to irradiate the structures with plasma.

5. The substrate processing method according to claim 1, wherein
the predetermined processing is processing to supply oxygen or an allotrope of oxygen to the structures.

6. The substrate processing method according to claim 1, wherein
the processing liquid dissolves gas present in each space between adjacent structures of the structures.

7. The substrate processing method according to claim 1, further comprising:
increasing hydrophobicity of the respective surfaces of the structures, by supplying a hydrophobizing agent to the structures after the supplying a processing liquid, from that before supply of the hydrophobizing agent; and
drying the substrate after the increasing hydrophobicity.

8. The substrate processing method according to claim 1, wherein
each distance between adjacent structures of the structures satisfies a prescribed condition, and
the prescribed condition is that a same processing liquid as the processing liquid is unable to permeate into the each space between adjacent structures of the structures before the increasing hydrophilicity.

9. The substrate processing method according to claim 8, wherein
the predetermined condition includes a first condition and a second condition,
the first condition is that the same processing liquid as the processing liquid is unable to permeate into the each space between the adjacent structures through capillary action before the increasing hydrophilicity, and
the second condition is that the processing liquid is enabled to permeate into the each space between the adjacent structures through the capillary action after the increasing hydrophilicity.

10. The substrate processing method according to claim 1, wherein
in the increasing hydrophilicity, hydrophilicity of a surface of a recess of each of the structures is increased from that before execution of the predetermined processing by executing the predetermined processing on the structures, and
the recess recesses from a side wall surface of each of the structures in a direction intersecting a direction in which the structure extends.

11. A semiconductor production method for producing a semiconductor by processing a semiconductor substrate with a pattern including a plurality of structures, the semiconductor being the processed semiconductor substrate, the method comprising:
increasing hydrophilicity of respective surfaces of the structures, by executing predetermined processing on the structures with a non-liquid substance, from that before execution of the predetermined processing; and
supplying a processing liquid to the structures after the increasing hydrophilicity.

12. A substrate processing apparatus for processing a substrate with a pattern including a plurality of structures, comprising:
a hydrophilizing section configured to execute predetermined processing on the structures with a non-liquid substance to increase hydrophilicity of respective surfaces of the structures from that before execution of the predetermined processing; and
a processing liquid supply section configured to supply a processing liquid to the structures after the time when the hydrophilicity of the respective surfaces of the structures is increased.

13. The substrate processing apparatus according to claim 12, further comprising
a removal liquid supply section configured to supply a removal liquid to the structures before the hydrophilicity of the respective surfaces of the structures is increased, the removal liquid being for removing oxide from the substrate.

14. The substrate processing apparatus according to claim 12, wherein
the predetermined processing is processing to irradiate the structures with ultraviolet rays.

15. The substrate processing apparatus according to claim 12, wherein
the predetermined processing is processing to irradiate the structures with plasma.

16. The substrate processing apparatus according to claim 12, wherein
the predetermined processing is processing to supply oxygen or an allotrope of oxygen to the structures.

17. The substrate processing apparatus according to claim 12, wherein
the processing liquid dissolves gas present in each space between adjacent structures of the structures.

18. The substrate processing apparatus according to claim 12, further comprising:
a hydrophobizing section configured to supply a hydrophobizing agent to the structures after time when the processing liquid is supplied to the structures to increase hydrophobicity of the respective surfaces of the structures from that before supply of the hydrophobizing agent; and
a drying section configured to dry the substrate after time when the hydrophobicity of the respective surfaces of the structures is increased.

19. The substrate processing apparatus according to claim 12, wherein
each distance between adjacent structures of the structures satisfies a prescribed condition, and
the prescribed condition is that a same processing liquid as the processing liquid is unable to permeate into each space between the adjacent structures before the hydrophilicity of the respective surfaces of the structures is increased.

20. The substrate processing apparatus according to claim 19, wherein
the predetermined condition includes a first condition and a second condition,
the first condition is that the same processing liquid as the processing liquid is unable to permeate into the space between the adjacent structures through capillary action before the hydrophilicity of the respective surfaces of the structures is increased, and
the second condition is that the processing liquid is enabled to permeate into the space between the adjacent structures through the capillary action after the hydrophilicity of the respective surfaces of the structures is increased.

21. The substrate processing apparatus according to claim 12, wherein
the hydrophilizing section increases hydrophilicity of a surface of a recess of each of the structures from that before execution of the predetermined processing by executing the predetermined processing on the structures, and
the recess recesses from a side wall surface of each of the structures in a direction intersecting a direction in which the structure extends.
